(19) United States
(12) Patent Application Publication
(10) Pub. No.: US 2025/0239936 A1
(43) Pub. Date: Jul. 24, 2025

(54) TECHNIQUES FOR SENSING CURRENT IN MULTIPHASE TRANS-INDUCTOR VOLTAGE REGULATORS

(71) Applicant: NVIDIA CORPORATION, Santa Clara, CA (US)

(72) Inventors: Haowei NIU, Shenzhen, Guangdong (CN); Shuai WANG, Shenzhen, Guangdong (CN); Huashi LI, Shenzhen, Guangdong (CN); Ziyi XU, Shenzhen, Guangdong (CN)

(21) Appl. No.: 18/698,743

(22) PCT Filed: Aug. 31, 2023
(86) PCT No.: PCT/CN2023/116046

§ 371 Date: Apr. 4, 2024

(51) Int. Cl. H02M 3/155; G01R 19/00; H02M 1/44

(52) U.S. Cl. CPC H02M 3/155; G01R 19/0092; H02M 1/44

(57) ABSTRACT

Disclosed is a trans-inductor voltage regulator that includes a first current sensing circuit, a second current sensing circuit, a filter, and a voltage regulator. The first current sensing circuit generates a first measurement associated with a current flowing through a primary winding of a transformer and the second current sensing circuit generates a second measurement associated with a current flowing through a compensation inductor coupled to a secondary winding of the transformer. The filter is coupled to the second current sensing and modifies the second measurement to generate a modified second measurement. In operation, the voltage regulator controls the switching module based on the first measurement and the measurement second measurement.

### BACKGROUND

### Field of the Various Embodiments

Embodiments of the present disclosure relate generally to electrical engineering and electronics and, more specifically, to techniques for sensing current in multiphase trans-inductor voltage regulators.

### Description of the Related Art

Various high-performance computing systems and devices, including datacenter server machines, storage systems, graphics processors, and personal computers, incorporate electronic components, such as processors, memory, high-current application-specific integrated circuits (ASICs) and/or field programmable gate arrays (FPGAs), that are powered using multiphase voltage regulators. However, conventional multiphase voltage regulator designs have not been able to keep pace with the increasing power demands of electronic components included in high-performance computing systems and devices. For example, to meet the transient performance requirements associated with the large power draws of these electronic components, which can exceed peaks of 1000 A of current, conventional multiphase voltage regulators have been designed to operate at high switching frequencies and/or to include large output capacitors. Both of these solutions reduce the operating efficiency of multiphase voltage regulators and increase costs.

In an effort to address the shortcomings of conventional multiphase voltage regulators, multiphase trans-inductor voltage regulators (TLVR) have been implemented in high-performance computing systems and devices. Notably, multiphase TLVRs have substantially faster transient responses than conventional multiphase voltage regulators that can match the load demands of electronic components included in high-performance computing systems and devices with respect to both amperage and bandwidth without sacrificing much power density, operating efficiency, and circuit board space.

FIG. 1 illustrates a circuit diagram of a multiphase TLVR 100 that can be used to power an electronic component included in a high-performance computing system or device, according to the prior art. As shown, the multiphase TLVR 100 includes a plurality of switching modules 105 (e.g., 105-1, 105-2, . . . , 105-N) that respectively generate a phase of the output voltage Vₒᵤₜ. For example, the first switching module 105-1 generates a first phase of the output voltage Vₒᵤₜ, and the second switching module 105-2 generates a second phase of the output voltage Vₒᵤₜ. As also shown, each switching module 105 is coupled to a primary winding of a corresponding transformer 110 such that the current output by a respective switching module 105 flows through the primary winding of the corresponding transformer 110. The secondary windings of each transformer 110 are grounded and coupled in series with a compensation inductor L_{c}.

In operation, a voltage regulator 115 included in the multiphase TLVR 100 controls the voltage output of the switching modules 105 based on a sensed current flowing through the multiphase TLVR 100. One approach to sensing current flowing through the multiphase TLVR 100 involves an inductor direct current resistance (DCR) current sensing technique. For example, the multiphase TLVR 100 includes a DCR sensing circuit 120 that is configured to sense the current flowing out of the switching module 105-1 and through the primary winding of the transformer 110-1.

Importantly, though, as shown in FIG. 1, the DCR sensing circuit 120 does not sense current flowing on the secondary side of the transformers 110, such as the current flowing through the secondary winding of the transformer 110-1 and/or the compensation inductor L_{c}. Without being able to sense current flowing on the secondary side of the transformers 110, the DCR sensing circuit 120 does not accurately measure the phase current or the total current flowing through the multiphase TLVR 100. In that regard, FIG. 2 illustrates an actual phase current flowing through the multiphase TLVR 100 and a measurement of the phase current flowing through the multiphase TLVR 100, according to the prior art. For example, FIG. 2 illustrates the phase current measurement that is generated by the DCR sensing circuit 120, which as shown, is distorted compared to the actual phase current flowing through the multiphase TLVR 100. Because the DCR sensing circuit 120 generates phase current measurements that do not accurately reflect the actual phase current flowing through the multiphase TLVR 100, the phase current measurements are unreliable as a bases for over-current-protection as well as current and voltage regulation. Accordingly, the multiphase TLVR 100 provides high-electronic components with less precise phase over-current-protection as well as less accurate current and voltage regulation.

As the foregoing illustrates, what is needed are more effective techniques for sensing current flow in multiphase trans-inductor voltage regulators.

### SUMMARY

Various embodiments set forth techniques for accurately sensing current in multiphase voltage regulators.

One embodiment of the present disclosure sets forth a trans-inductor voltage regulator that includes a first current sensing circuit that generates a first measurement associated with a current flowing through a primary winding of a transformer. The trans-inductor voltage regulator further includes a second current sensing circuit that generates a second measurement associated with a current flowing through a compensation inductor coupled to a secondary winding of the transformer. That trans-inductor voltage regulator further includes a filter that is coupled to the second current sensing circuit and modifies the second measurement to generate a modified second measurement. In operation, a voltage regulator included in the trans-inductor voltage regulator controls a switching module based on the first measurement and the modified second measurement.

At least one technical advantage of the disclosed techniques relative to the prior art is that, with the disclosed techniques, phase current flowing through a multiphase TLVR can be accurately sensed. More specifically, with the disclosed techniques, an accurate phase current measurement and an accurate total current measurement can be generated by sensing the current flowing through a primary winding of a transformer included in a multiphase TLVR and by sensing current flowing through a compensation inductor coupled in series with the secondary windings of the transformers included in the multiphase TLVR. Accordingly, with the disclosed techniques, accurate phase current and total current measurements can be generated, thereby improving the overall performance of the multiphase TLVR relative to what can be achieved using prior art designs. Consequently, with the disclosed techniques, a multiphase TLVR can provide electronic components more accurate current and voltage regulation as well as enhanced phase over-current-protection. These technical advantages represent one or more technological improvements over prior art approaches.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a circuit diagram of a multiphase trans-inductor voltage regulator (TLVR) that can be used to power a high-performance electronic component, according to the prior art;

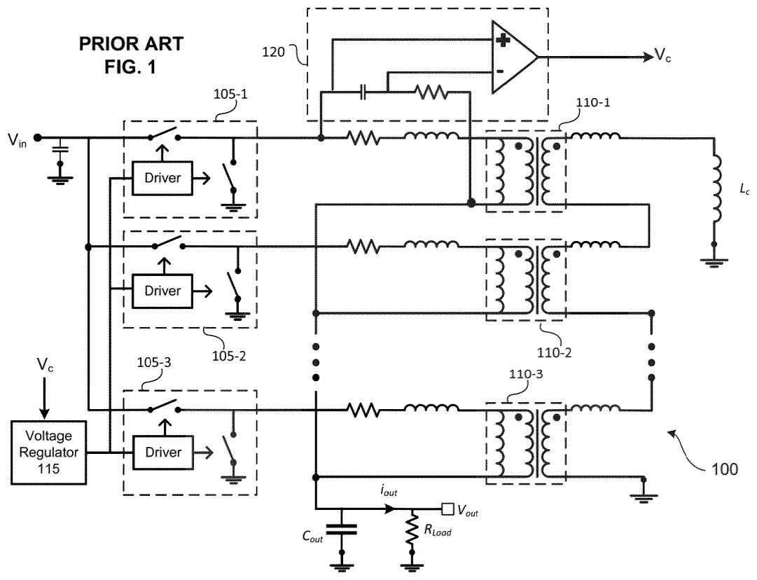

FIG. 2 illustrates an actual phase current flowing through the multiphase TLVR of FIG. 1 and a measurement of the phase current flowing through the multiphase TLVR of FIG. 1, according to the prior art;

FIG. 3 illustrates a circuit diagram of a multiphase TLVR, according to various embodiments;

FIG. 4 is a more detailed illustration of the voltage regulator included of FIG. 3, according to various embodiments;

FIG. 5 illustrates a circuit diagram of a multiphase TLVR, according to other various embodiments;

FIG. 6 sets forth a flowchart of method steps for sensing current in a multiphase TLVR, according to various embodiments;

FIG. 7 illustrates an actual phase current and a measurement of that phase current when a multiphase TLVR is operating in a steady state, according to various embodiments;

FIG. 8 illustrates an actual phase current and a measurement of that phase current when a multiphase TLVR is operating in a dynamic state, according to various embodiments;

FIG. 9 illustrates a circuit diagram of a voltage regulator that may be incorporated into a multiphase TLVR, according to other various embodiments.

FIG. 10 illustrates an actual total current and a measurement of that total current when a multiphase TLVR implementing the voltage regulator of FIG. 9 is operating in a steady state, according to other various embodiments; and

FIG. 11 illustrates an actual total current and a measurement of that total current when a multiphase TLVR implementing the voltage regulator of FIG. 9 is operating in a dynamic state, according to various embodiments.

FIG. 12 illustrates a computer system configured to implement one or more aspects of the various embodiments.

### DETAILED DESCRIPTION

In the following description, numerous specific details are set forth to provide a more thorough understanding of the embodiments of the present disclosure. However, it will be apparent to one of skill in the art that the embodiments of the present disclosure may be practiced without one or more of these specific details.

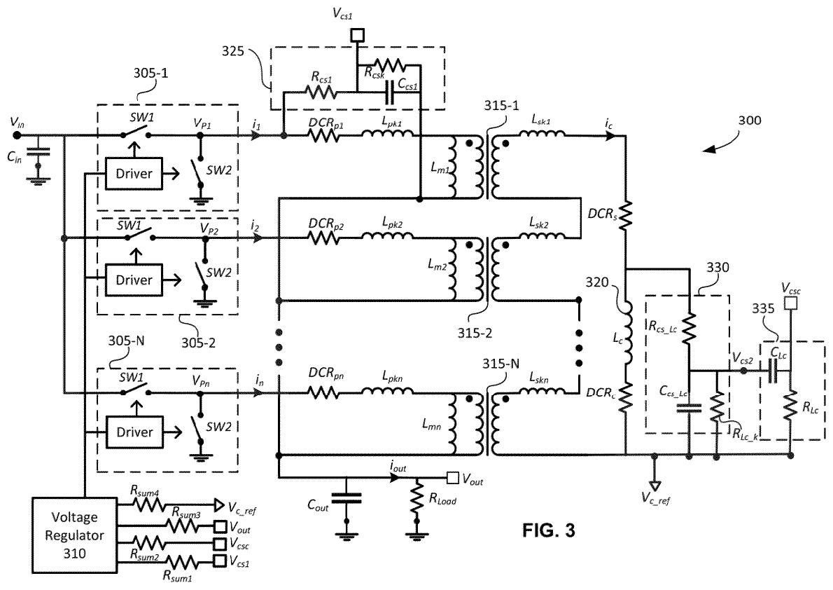

FIG. 3 illustrates a circuit diagram of a multiphase TLVR 300, according to various embodiments. The multiphase TLVR 300 is configured to receive an input voltage Vin and provide an output voltage Vₒᵤₜ to a load. In the illustrated example of FIG. 3, the load is represented as a resistive load R_{load} that consumes a current iₒᵤₜ. In some examples, the load is an electronic component, such as a processor, a memory, a high-current application-specific integrated circuit (ASIC), and/or a field programmable gate array (FPGA), incorporated in a high-performance computing system or device. As persons skilled in the art will appreciate, a high-performance computing system or device that includes the load powered by the multiphase TLVR 300 can be any type of technically feasible computer system, including, without limitation, a server machine, a server platform, a desktop machine, a laptop machine, a hand-held/mobile device, or a wearable device. Furthermore, persons skilled in the art will understand that the multiphase TLVR 300 can also be used to power other types of components.

The multiphase TLVR 300 includes a plurality of switching modules 305 (e.g., 305-1, 305-2, . . . , 305-N) that respectively generate a phase of the output voltage Vₒᵤₜ. For example, the first switching module 305-1 generates a first phase voltage V_{P1}, the second switching module 305-2 generates a second phase voltage V_{P2}, and the Nth switch module 305-N generates an Nth phase voltage V_{Pn}. Moreover, each switching module 305 generates a respective phase current. For example, the first switching module 305-1 generates a first phase current i₁, the second switching module 305-2 generates a second phase current i₂, and the Nth switch module 305-N generates an Nth phase current iₙ

As shown in FIG. 3, each switching module 305 includes a first switch SW1, a second switch SW2, and a driver that controls operation of the first and second switches SW1, SW2 in accordance with control signals received from a voltage regulator 310. When the first switch SW1 is turned ON, or closed, the switching module 305 is coupled to the input voltage Vᵢₙ such that the switching module 305 generates a respective phase voltage Vₚ. When the first switch SW1 is turned OFF, or is open, the switching module 305 is disconnected from the input voltage Vᵢₙ. When the second switch SW2 is turned ON, the switching module 305 is coupled to ground. When the second switch SW2 is turned OFF, the switching module 305 is disconnected from ground. In the illustrated example of FIG. 3, each switching module 305 includes two switches and one driver. However, in some embodiments, each switching module 305 includes a different number of switches and/or drivers.

As will be described in more detail herein, in operation, the voltage regulator 310 generates one or more control signals for controlling operation of the switching modules 305 based on measurements indicative of and/or associated with currents flowing through the multiphase TLVR 300. For example, the voltage regulator 310 generates one or more pulse-width modulation (PWM) signals based on measurements indicative of and/or associated with currents flowing through the multiphase TLVR 300. In operation, the voltage regulator 310 applies the one or more control signals (e.g., PWM signals) to the drivers included in the switching modules 305 to control the frequency and/or the duty cycle at which the first and/or second switches SW1, SW2 included in the switching modules 305 are turned ON and OFF. Stated another way, the voltage regulator 310 controls the turning ON and OFF the first and/or second switches SW1, SW2 included in the switching modules 305 with one or more control signals that are generated based on measurements associated with currents flowing through the multiphase TLVR 300. The voltage regulator 310 can be implemented as any suitable control device and/or circuit for controlling operation of switching modules 305. For example, voltage regulator 310 can be implemented as one or more of an analog control circuit, a digital control circuit, a microprocessor, an integrated circuit, and/or any other suitable control device for controlling operation of switching modules 305. As another example, voltage regulator 310 is implemented as a PWM controller.

As further shown in FIG. 3, the multiphase TLVR 300 includes a plurality of transformers 315 (e.g., 315-1, 315-2, . . . , 305-N). Each transformer 315 includes a primary winding that is coupled to the output of a respective switching module 305 such that the phase current i generated by a respective switching module 305 flows through the primary winding of the transformer 315. For example, the primary winding included in the first transformer 315-1 is coupled to the output of the first switching module 305-1 such that the first phase current i₁ generated by the first switching module 305-1 flows through the primary winding of the first transformer 315-1. Similarly, the primary winding included in the second transformer 315-2 is coupled to the output of the second switching module 305-2 such that the second phase current i₂ generated by the second switching module 305-2 flows through the primary winding of the second transformer 315-2. Moreover, the primary winding included in the Nth transformer 315-N is coupled to the output of the Nth switching module 305-N such that the Nth phase current in generated by the Nth switching module 305-N flows through the primary winding of the Nth transformer 315-N.

In the illustrated example of FIG. 3, the direct current (DC) resistance DCRₚ of the primary winding of a transformer 315 is modeled as a resistor that is coupled in series with the primary winding of the transformer 315. For example, the DC resistance DCRₚ₁ of the primary winding of the first transformer 315-1 is modeled as a resistor coupled in series with the primary winding of the first transformer 315-1. Similarly, the leakage inductance Lₚₖ of the primary winding of a transformer 315 is modeled as an inductor that is coupled in series with the primary winding of the transformer 315. For example, the leakage inductance Lₚₖ₁ of the primary winding of the first transformer 315-1 is modeled as an inductor that is coupled in series with the primary winding of the first transformer 315-1. The mutual inductance Lₘ of each transformer 315 is modeled as an inductor that is coupled in parallel with the primary winding of the transformer 315. For example, the mutual inductance Lₘ₁ of the first transformer 315-1 is modeled as an Inductor that Is coupled in parallel with the primary winding of the first transformer 315-1.

Each transformer 315 further includes a secondary winding. As shown in FIG. 3, the secondary windings of the plurality of transformers 315 are coupled in series with each other. For example, the secondary winding of the first transformer 315-1 is coupled in series with the secondary windings of the second transformer 315-2 and the Nth transformer 315-N. The secondary winding of the Nth transformer 315-N is also coupled to a reference voltage V_{c_ref}. In the illustrated example of FIG. 3, the combined DC resistance DCRₛ of the secondary windings of the plurality of transformers 315 is modeled as a resistor that is coupled in series with the secondary windings of the transformers 315. The leakage inductance Lₛₖ of the secondary winding of a transformer 315 is modeled as an inductor that is coupled in series with the secondary winding of the transformer 315. For example, the leakage inductance Lₛₖ₁ of the secondary winding of the first transformer 315-1 is modeled as an inductor that is coupled in series with the secondary winding of the first transformer 315-1.

The multiphase TLVR 300 further includes a compensation inductor 320 that is coupled between the secondary winding of the first transformer 315-1 and the reference voltage V_{c_ref}. Moreover, the compensation inductor 320 is coupled in series with the secondary windings of each transformer 315. Thus, the current i_{c} that flows through compensation inductor 320 is the same current that flows through the secondary windings of the transformers 315. The compensation inductor 320 has an inductance L, and a DC winding resistance DCR, that is modeled as a resistor coupled in series with the compensation inductor 320. The value of the reference voltage V_{c_ref} can be adjusted and set to any desired value, such as 5V, 2.5V, or some other value. In some examples, the value of the reference voltage V_{c_ref} is non-zero. In some examples, the value of the reference voltage V_{c_ref} is zero.

As described above, the voltage regulator 310 controls operation of the switching modules 305. In some examples, the voltage regulator 310 controls operation of the switching modules 305 based on a phase current, such as the first phase current i₁, flowing through the multiphase TLVR 300. As will be described in more detail below, the voltage regulator 310 controls operation of the switching modules 305 based on a first measurement indicative of, or associated with, the first phase current i₁ flowing through the primary winding of the first transformer 315-1 and a second measurement indicative of, or associated with, the current i, flowing through the compensation inductor 320. In some examples, the voltage regulator 310 combines the first measurement associated with the first phase current i₁ flowing through the primary winding of the first transformer 315-1 and the second measurement associated with the current i_{c} flowing through the compensation inductor 320 into a combined measurement associated with the total first phase current flowing through the multiphase TLVR 300. In such examples, the voltage regulator 310 controls operation of the switching modules 305 based on the combined measurement associated with the total first phase current flowing through the multiphase TLVR 300. In some embodiments, the voltage regulator 310 generates one or more control signals based on the first measurement associated with the first phase current i₁ flowing through the primary winding of the first transformer 315-1, the second measurement associated with the current i, flowing through the compensation inductor 320, and/or the combined measurement associated with the total first phase current flowing through the multiphase TLVR 300 and controls the switching modules 305 in accordance with the one or more control signals.

As shown in FIG. 3, the multiphase TLVR 300 includes a first current sensing circuit 325 that is configured to sense the first phase current i₁ flowing through the primary winding of the first transformer 315-1. The first current sensing circuit 325 includes a current sense resistor R_{cs1}, a current sense capacitor C_{cs1}, and an optional gain adjusting resistor R_{csk} that is coupled in parallel with the current sense capacitor C_{cs1}. The first terminal of the current sense resistor R_{cs1} is coupled to an input side of the primary winding of the first transformer 315-1 and the second terminal of the current sense resistor R_{cs1} is coupled to the first terminal of the current sense capacitor C_{cs1}. The second terminal of the current sense capacitor C_{cs1} is coupled to the output side of the primary winding of the first transformer 315-1.

In operation, the first current sensing circuit 325 senses a voltage across the primary winding of the first transformer 315-1 and generates a first measurement V_{cs1} of the voltage at the first terminal of the current sense capacitor C_{cs1}. In the illustrated example of FIG. 3, the voltage across the primary winding of the first transformer 315-1 is the series voltage across the DC resistance DCRₚ₁ of the primary winding of the first transformer 315-1, the leakage inductance Lₚₖ₁ of the primary winding of the first transformer 315-1, and the mutual inductance Lₘ₁ of the first transformer 315-1. The first measurement V_{cs1} generated by first current sensing circuit 325 is indicative of, or associated with, the first phase current i₁ flowing through the primary winding of the first transformer 315-1. This first measurement V_{cs1} is provided as an input to the voltage regulator 310 for controlling operation of the switching modules 305.

In the illustrated example of FIG. 3, the first current sensing circuit 325 is implemented as a low-pass filter. Stated another way, the components included in the first current sensing circuit 325 are arranged in a low-pass filter configuration. In operation, the first current sensing circuit 325 filters out, or removes, the high-frequency characteristics of the voltage across the primary winding of the first transformer 315-1 when generating the first measurement V_{cs1}. Accordingly, the value of the first measurement V_{cs1} is the value of the low-frequency characteristics of the voltage across the primary winding of the first transformer 315-1. The high-frequency characteristics of the voltage across the primary winding of the first transformer 315-1 refer to the components of the voltage across the primary winding of the first transformer 315-1 that have frequencies that are greater than a cutoff frequency and the low-frequency characteristics of the voltage across the primary winding of the first transformer 315-1 refer to the components of the voltage across the primary winding of the first transformer 315-1 that have frequencies that are less than the cutoff frequency. The value of this cutoff frequency is dependent on the resistance of the current sense resistor R_{cs1} and the capacitance of the current sense capacitor C_{cs1}.

As described above, this first measurement V_{cs1} is indicative of, or associated with, the first phase current i, flowing through the primary winding of the first transformer 315-1. In particular, this first measurement V_{cs1} is indicative of, or associated with, the value of the complete frequency characteristics of the first phase current i₁ flowing through the primary winding of the first transformer 315-1 minus the high-frequency characteristics of the current i_{c} flowing out of the secondary winding of the first transformer 315-1 and through the compensation inductor 320. That is, the first measurement V_{cs1} is indicative of the value of the complete frequency characteristics of the first phase current i, flowing through the primary winding of the first transformer 315-1 without the high-frequency characteristics of the current i_{c} flowing through the compensation inductor 320.

The complete frequency characteristics of the first phase current i-flowing through the primary winding of the first transformer 315-1 refers to both the low-frequency components and the high-frequency components of the first phase current i₁ flowing through the primary winding of the first phase current i-flowing through the primary winding of the first transformer 315-1. Stated another way, the complete frequency characteristics of the first phase current i-flowing through the primary winding of the first transformer 315-1 simply refers to the first phase current i₁ flowing through the primary winding of the first transformer 315-1. The high-frequency characteristics of the current i_{c} flowing through the compensation inductor 320 refer to the components of the current i_{c} flowing through the compensation inductor 320 that have frequencies that are greater than the cutoff frequency and the low-frequency characteristics of the current i_{c} flowing through the compensation inductor 320 refer to the components of the current i_{c} flowing through the compensation inductor 320 that have frequencies that are less than the cutoff frequency. As described above, the value of this cutoff frequency is dependent on the resistance of the current sense resistor Rest and the capacitance of the current sense capacitor C_{cs1}.

Therefore, the first measurement V_{cs1} generated by the first current sensing circuit 325 is indicative of, or associated with, the value of the first phase current i₁ flowing through the primary winding of the first transformer 315-1 minus the high-frequency characteristics of the current i_{c} flowing through the compensation inductor 320 that is coupled to the secondary winding of the secondary winding of the first transformer 315-1. The value of the first measurement V_{cs1} can be expressed in the s-domain using Equation 1:

$${V}_{c s 1} ( s ) = DC {R}_{p 1} \times {i}_{1} ( s ) - \frac{s {L}_{m 1} \times {i}_{c} ( s )}{1 + s {R}_{C S 1} {C}_{C S 1}} + {V}_{o u t} ( s ) \qquad ( 1 )$$

Where Vest is the first measurement, DCRₚ₁ is the DC resistance of the primary winding of the first transformer 315-1, i₁(s) is the first phase current flowing through the primary winding of the first transformer 315-1, i_{c}(s) is the current flowing through the compensation inductor 320, R_{cs1} is the resistance of the current sense resistor, C_{cs1} is the capacitance of the current sense capacitor, Lₘ₁ is the mutual inductance of the first transformer 315-1, and Vₒᵤₜ(s) is the output voltage.

As shown in FIG. 3, the multiphase TLVR 300 further includes a second current sensing circuit 330 that is configured to sense the current i, flowing through the compensation inductor 320. The second current sensing circuit 330 includes a current sense resistor R_{cs_Lc}, a current sense capacitor C_{cs_Lc}, and an optional gain adjusting resistor R_{Lc_k}. The first terminal of the current sense resistor R_{cs_Lc} is coupled to the input terminal of the compensation inductor 320 and the second terminal of the current sense resistor R_{cs_Lc} is coupled to the first terminal of the current sense capacitor C_{cs_Lc}. The second terminal of the current sense capacitor C_{cs_Lc} is coupled to the reference voltage V_{c_ref}. The optional gain adjusting resistor R_{Lc_k} is coupled in parallel with current sense capacitor C_{cs_Lc}.

In operation, the second current sensing circuit 330 senses a voltage across the compensation inductor 320 and generates a second measurement V_{cs2} of the voltage at the first terminal of the current sense capacitor C_{cs_Lc}. In the illustrated example of FIG. 3, the voltage across the compensation inductor 320 is the series voltage across the compensation inductor 320 and the DC winding resistance DCR_{c}. The second measurement V_{cs2} generated by the second current sensing circuit 330 is indicative of, or associated with, the current i_{c} flowing through the compensation inductor 320.

In the illustrated example of FIG. 3, the second current sensing circuit 330 is implemented as a low-pass filter. Stated another way, the components included in the second current sensing circuit 330 are arranged in a low-pass filter configuration. In operation, the second current sensing circuit 330 filters out, or removes, the high-frequency characteristics of the voltage across the compensation inductor 320 when generating the second measurement V_{cs2}. Accordingly, the value of the second measurement V_{cs2} is the value of the low-frequency characteristics of the voltage across the compensation inductor 320. The high-frequency characteristics of the voltage across the compensation inductor 320 refer to the components of the voltage across the compensation inductor 320 that have frequencies that are greater than a cutoff frequency and the low-frequency characteristics of the voltage across the compensation inductor 320 refer to the components of the voltage across the compensation inductor 320 that have frequencies that are less than the cutoff frequency. The value of this cutoff frequency is dependent on the resistance of the current sense resistor R_{cs_Lc} included in the second current sensing circuit 330 and the capacitance of the current sense capacitor C_{cs_Lc} included in the second current sensing circuit 330.

The second measurement V_{cs2} is indicative of, or associated with, the current i_{c} flowing through the compensation inductor 320. In particular, the second measurement V_{cs2} is indicative of, or associated with, the complete frequency characteristics of the current i_{c} flowing through the compensation inductor 320, where the complete frequency characteristics of the current i, flowing through the compensation inductor 320 refers to both the low-frequency characteristics and the high-frequency characteristics of the current i_{c} flowing through the compensation inductor 320. As described above, the first measurement V_{cs1} generated by the first current sensing circuit 325 is indicative of, or associated with, a value of the first phase current i₁ flowing through the primary winding of the first transformer 315-1 minus the high-frequency characteristics of the current i, flowing through the compensation inductor 320. Therefore, if the first measurement V_{cs1} is combined with the high-frequency characteristics included in the second measurement V_{cs2}, the resultant measurement would be a signal indicative of, or associated with, the value of the first phase current i₁ flowing through the primary winding of the first transformer 315-1.

Accordingly, the multiphase TLVR 300 further includes a filter 335 that is configured to filter, or modify, the second measurement V_{cs2}. In particular, the filter 335 is implemented as a high-pass filter that filters out the low-frequency characteristics from the second measurement V_{cs2}. The filter 335 includes a current sense capacitor C_{Lc} and a current sense resistor R_{Lc}. The first terminal of the current sense capacitor C_{Lc} is coupled to the output of the second current sensing circuit 330 (e.g., at the first terminal of the current sense capacitor C_{cs_Lc}) and the second terminal of the current sense capacitor C_{Lc} is coupled to the first terminal of the current sense resistor R_{Lc}. The current sense resistor R_{Lc} is coupled between the second terminal of the current sense capacitor C_{Lc} and the reference voltage V_{c_ref}.

In operation, the filter 335 generates, based on the second measurement V_{cs2}, a modified second measurement V_{csc} at the first terminal of the current sense resistor R_{Lc}. This modified second measurement V_{csc} includes the high-frequency characteristics of the second measurement V_{cs2}, and thus, is indicative of, or associated with, the high-frequency characteristics of the current i_{c} flowing through the compensation inductor 320. Here, the high-frequency characteristics of the current i_{c} flowing through the compensation inductor 320 refer to components of the current i_{c} flowing through the compensation inductor 320 that have frequencies that are greater than a cutoff frequency. Moreover, this modified second measurement V_{csc} does not include the low-frequency characteristics of the second measurement V_{cs2}, as the filter 335 filters out, or removes, the low-frequency characteristics from the second measurement V_{cs2}. Here, the low-frequency characteristics of the current i_{c} flowing through the compensation inductor 320 refer to components of the current i_{c} flowing through the compensation inductor 320 that have frequencies that are less than the cutoff frequency. The value of this cutoff frequency is dependent on the resistance of the current sense resistor R_{Lc} included in the filter 335 and the capacitance of the current sense capacitor C_{Lc} included in the filter 335. In some examples, this cutoff frequency is equal to the cutoff frequency that is dependent on the resistance of the current sense resistor R_{cs1} and the capacitance of the current sense capacitor C_{cs1} included in the first current sensing circuit 325.

In summary, the modified second measurement V_{csc} generated by the filter 335 is indicative of, or associated with, the high-frequency characteristics of the current i_{c} flowing through the compensation inductor 320. As will be described in more detail herein, the filter 335 outputs the modified second measurement V_{csc} to the voltage regulator 310 for controlling operation of the switching modules 305. The value of the modified second measurement V_{csc} can be expressed in the s-domain using Equation 2:

$${V}_{c s c} ( s ) = DC {R}_{c} \times {i}_{c} ( s ) \times \frac{s {R}_{cs\_Lc} {C}_{cs\_Lc}}{1 + s {R}_{L c} {C}_{L c}} + {V}_{c\_ref} ( s ) \qquad ( 2 )$$

Where V_{csc} is the modified second measurement, DCR_{c} is the DC resistance of the compensation inductor L_{c}, i_{c}(s) is the current flowing through the compensation inductor 320, R_{cs_Lc} is the resistance of the current sense resistor included in the second current sensing circuit 330, C_{cs_Lc} is the capacitance of the current sense capacitor included in the second current sensing circuit 330, R_{Lc} is the resistance of the current sense resistor included in the filter 335, C_{Lc} is the capacitance of the current sense capacitor included in the filter 335, and V_{c_ref} is the reference voltage.

In operation, the voltage regulator 310 controls operation of the switching modules 305 based at least on first measurement V_{cs1} generated by the first current sensing circuit 325 and the modified second measurement V_{csc} generated by the filter 335, which is a modified version of the second measurement V_{cs2} generated by the second current sensing circuit 330. For example, the voltage regulator 310 generates one or more control signals based on the first measurement V_{cs1} and the modified second measurement V_{csc} and controls operation of the switching modules 305 with the control signals, as described above. In some examples, the voltage regulator 310 combines the first measurement V_{cs1} and the modified second measurement V_{csc} into a combined measurement V_{cs_final} indicative of the total first phase current flowing through the multiphase TLVR 300 and controls operation of the switching modules 305 based on the combined measurement V_{cs_final}. For example, the voltage regulator 310 generates one or more control signals based on the combined measurement V_{cs_final} and controls operation of the switching modules 305 with the control signals, as described above. In some examples, the voltage regulator 310 further controls the switching modules 305 based on the output voltage Vₒᵤₜ of the multiphase TLVR 300 and/or the reference voltage V_{c_ref}. In such examples, the voltage regulator 310 generates the one or more control signals for controlling the switching modules 305 based on one or more of the output voltage Vₒᵤₜ, the reference voltage V_{c_ref}, the first measurement V_{cs1}, the modified second measurement V_{csc}, and/or the combined measurement V_{cs_final}. As described herein, in some examples, the one or more control signals generated by the voltage regulator 310 for controlling operation of the switching modules 305 are PWM signals.

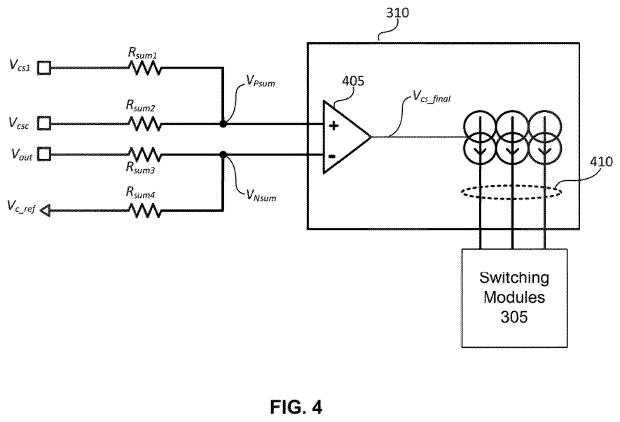

FIG. 4 is a more detailed illustration of the voltage regulator 310 included in FIG. 3, according to various embodiments. As shown in FIG. 4, the voltage regulator 310 controls operation of the switching modules 305 based on the first measurement V_{cs1}, the modified second measurement V_{csc}, the output voltage Vₒᵤₜ, and the reference voltage V_{c_ref}, which are provided as inputs to the voltage regulator 310. As further shown in FIG. 4, each of the respective inputs to the voltage regulator 310 is coupled in series with a respective input summing resistance Rₛᵤₘ coupled to the voltage regulator 310. For example, the first measurement V_{cs1} is coupled in series with the first summing resistance Rₛᵤₘ₁ coupled to the voltage regulator 310, the modified second measurement V_{csc} is coupled in series with the second summing resistance Rₛᵤₘ₂ coupled to the voltage regulator 310, the output voltage Vₒᵤₜ is coupled in series with the third summing resistance Rₛᵤₘ₃ coupled to the voltage regulator 310, and the output voltage V_{c_ref} is coupled in series with the fourth summing resistance Rₛᵤₘ₄ coupled to the voltage regulator 310.

In operation, the voltage regulator 310 combines the first measurement V_{cs1} with the modified second measurement V_{csc} into a positive combined measurement V_{P_sum}. The positive combined measurement V_{P_sum}, which is associated with the total first phase current flowing through the multiphase TLVR 300, is provided as an input to the positive terminal of the comparator 405 included in the voltage regulator 310. The value of the positive combined measurement V_{P_sum} can be expressed in the s-domain using Equation 3:

$${V}_{P\_sum} ( s ) = \frac{{R}_{sum 2}}{{R}_{sum 1} + {R}_{sum 2}} DC {R}_{p 1} \times {i}_{1} ( s ) + \frac{{R}_{sum 2}}{{R}_{s u m 1} + {R}_{sum 2}} {V}_{o u t} ( s ) + \frac{{R}_{sum 1}}{{R}_{s u m 1} + {R}_{sum 2}} {V}_{c\_ref} ( s ) \qquad ( 3 )$$

Where V_{P_sum} is the positive combined measurement, DCRₚ₁ is the DC resistance of the primary winding of the first transformer 315-1, i₁ (s) is the first phase current flowing through primary winding of the first transformer 315-1, Vₒᵤₜ(s) is the output voltage, V_{c_ref}(s) is the reference voltage, Rₛᵤₘ₁ is the first summing resistance, and Rₛᵤₘ₂ is the second summing resistance.

As further shown in FIG. 4, in operation, the voltage regulator 310 combines the output voltage Vₒᵤₜ and the reference voltage V_{c_ref} into a negative combined measurement V_{N_sum}. This negative combined measurement V_{N_sum} is provided as an input to the negative terminal of the comparator 410 included in the voltage regulator 310. The value of the negative combined measurement V_{N_sum} can be expressed in the s-domain using Equation 4:

$${V}_{N\_sum} ( s ) = \frac{{R}_{sum 4}}{{R}_{sum 3} + {R}_{s u m 4}} {V}_{o u t} ( s ) + \frac{{R}_{sum 3}}{{R}_{s u m 3} + {R}_{s u m 4}} {V}_{c\_ref} ( s ) \qquad ( 4 )$$

Where V_{N_sum} is the combined measurement, Vₒᵤₜ(s) is the output voltage, V_{c_ref}(s) is the reference voltage, Rₛᵤₘ₃ is the third summing resistance, and Rₛᵤₘ₄ is the fourth summing resistance.

Based on the positive combined measurement V_{P_sum} input to the positive terminal and the negative combined measurement V_{N_sum} input to the negative terminal, the comparator 405 generates a combined measurement V_{cs_final} that is indicative of the total first phase current flowing through the multiphase TLVR 300. When the value of the first summing resistance Rₛᵤₘ₁ is equal or approximately equal to the value of the third summing resistance Rₛᵤₘ₃, and the value of the second summing resistance Rₛᵤₘ₂ is equal or approximately equal to the value of the fourth summing resistance Rₛᵤₘ₄, the value of the combined measurement V_{cs1_final} can be expressed in the s-domain using Equation 5:

$${V}_{cs 1\_ final} = {V}_{P\_sum} ( s ) - {V}_{N\_sum} ( s ) = \frac{{R}_{s u m 2}}{{R}_{s u m 1} + {R}_{sum 2}} DC {R}_{p 1} \times {i}_{1} ( s ) \qquad ( 5 )$$

Where V_{cs1_final} is the final measurement, Rₛᵤₘ₁ is the first summing resistance, Rₛᵤₘ₂ is the second summing resistance, DCRₚ₁ is the DC resistance of the primary winding of the first transformer 315-1, and i₁(s) is the first phase current flowing through primary winding of the first transformer 315-1.

The voltage regulator 310 then generates one or more control signals 410 based on the combined measurement V_{cs_final} and controls operation of the switching modules 305 with the one or more control signals 410. As described above, the combined measurement V_{cs_final} is indicative of the total first phase current flowing through the multiphase TLVR 300. The total first phase current refers to the complete frequency characteristics of the of the first phase current i₁ generated by the first switching module 305-1. For example, as the first measurement V_{cs1} is associated with the complete frequency characteristics of the first phase current i₁ flowing through the primary winding of the first transformer 315-1 minus the high-frequency characteristics of the current i_{c} flowing through the compensation inductor 320 and the modified second measurement V_{csc} is associated with the high-frequency characteristics of the current i_{c} flowing through the compensation inductor 320, when the first measurement V_{cs1} is combined with the second measurement V_{csc} to generate the combined measurement V_{cs_final}, the combined measurement V_{cs_final} is indicative of, or associated, with the complete frequency characteristics of the total first phase current that is generated by the first switching module 305-1. As described herein, in some examples, the one or more control signals 410 are PWM signals.

In operation, the voltage regulator 310 controls operation of the switching modules 305 with the one or more control signals 410 that are generated based on the combined measurement V_{cs_final}. For example, the voltage regulator 310 applies the one or more control signals 410 to the drivers included in the switching modules 305 to control the frequency and/or the duty cycle at which the first and/or second switches SW1, SW2 included in the switching modules 305 are turned ON and OFF. Stated another way, the voltage regulator 310 controls the turning ON and OFF of the first and/or second switches SW1, SW2 included in the switching modules 305 with the one or more control signals 410 that were generated based on the combined measurement V_{cs_final}.

In the illustrated example of FIG. 3, the multiphase TLVR 300 includes a second current sensing circuit 330 that is implemented as a low-pass filter and a filter 335 that is implemented as a high-pass filter. However, in some embodiments, a multiphase TLVR can include a second current sensing circuit and/or a filter that is implemented as a different type of circuit.

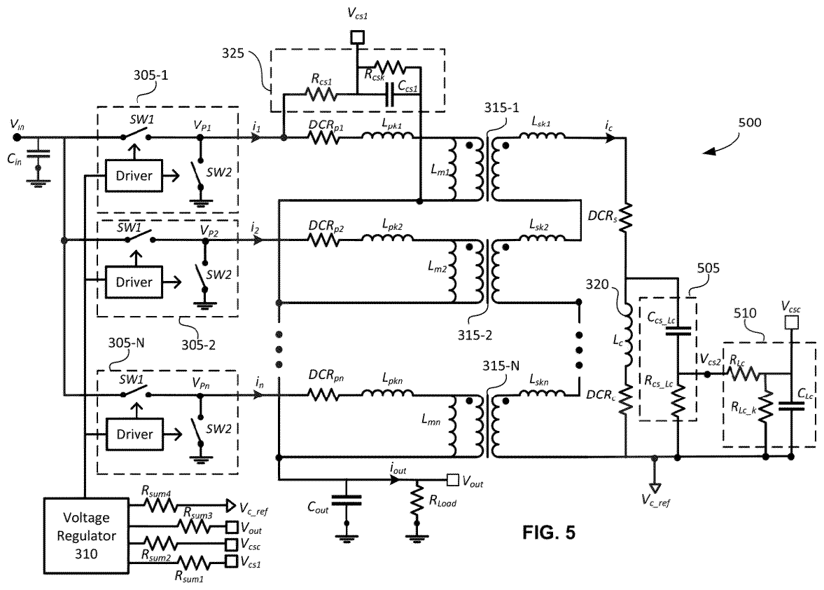

FIG. 5 illustrates a circuit diagram of a multiphase TLVR 500, according to other various embodiments. The multiphase TLVR 500 is similar in construction and operation to the multiphase TLVR 300 of FIG. 3. However, the multiphase TLVR 500 differs from the multiphase TLVR 300 because the multiphase TLVR 500 includes a second current sensing circuit 505 that is implemented as a high-pass filter and a filter 510 that is implemented as a low-pass filter.

Similar to the multiphase TLVR 300, the multiphase TLVR 500 is configured to receive an input voltage Vᵢₙ and provide an output voltage Vₒᵤₜ to a load. In the illustrated example of FIG. 5, the load is represented as a resistive load R_{load} that consumes a current iₒᵤₜ. In some examples, the load is an electronic component, such as a processor, a memory, a high-current application-specific integrated circuit (ASIC), and/or a field programmable gate array (FPGA), incorporated in a high-performance computing system or device. As persons skilled in the art will appreciate, a high-performance computing system or device that includes the load powered by the multiphase TLVR 500 can be any type of technically feasible computer system, including, without limitation, a server machine, a server platform, a desktop machine, a laptop machine, a hand-held/mobile device, or a wearable device. Furthermore, persons skilled in the art will understand that the multiphase TLVR 500 can also be used to power other types of components.

As shown in FIG. 5, the second current sensing circuit 505 is configured to sense the current i_{c} flowing through the compensation inductor 320. The second current sensing circuit 505 includes a current sense capacitor C_{cs_Lc} and a current sense resistor R_{cs_Lc}. The first terminal of the current sense capacitor C_{cs_Lc} is coupled to the input terminal of the compensation inductor 320 and the second terminal of the current sense capacitor C_{cs_Lc} is coupled to the first terminal of the current sense resistor R_{cs_Lc}. The second terminal of the current sense resistor R_{cs_Lc} is coupled to the reference voltage V_{c_ref}. In operation, the second current sensing circuit 505 senses a voltage across the compensation inductor 320 and generates a second measurement V_{cs2} of the voltage at the first terminal of the current sense resistor R_{cs_Lc}. In the illustrated example of FIG. 3, the voltage across the compensation inductor 320 is the series voltage across the compensation inductor 320 and the DC winding resistance DCR_{c}. This second measurement V_{cs2} generated by the second current sensing circuit 505 is indicative of, or associated with, the current i_{c} flowing through the compensation inductor 320.

In the illustrated example of FIG. 5, the second current sensing circuit 505 is implemented as a high-pass filter. Stated another way, the components included in the second current sensing circuit 505 are arranged in a high-pass filter configuration. In operation, the second current sensing circuit 505 filters out, or removes, the low-frequency characteristics of the voltage across the compensation inductor 320 when generating the second measurement V_{cs2}. Accordingly, the value of the second measurement V_{cs2} is the value of the high-frequency characteristics of the voltage across the compensation inductor 320. The low-frequency characteristics of the voltage across the compensation inductor 320 refer to the components of the voltage across the compensation inductor 320 that have frequencies that are less than a cutoff frequency and the high-frequency characteristics of the voltage across the compensation inductor 320 refer to the components of the voltage across the compensation inductor 320 that have frequencies that are greater than a cutoff frequency. The value of this cutoff frequency is dependent on the resistance of the current sense resistor R_{cs_Lc} included in the second current sensing circuit 505 and the capacitance of the current sense capacitor C_{cs_Lc} included in the second current sensing circuit 505.

The second measurement V_{cs2} is indicative of, or associated with, the current i_{c} flowing through the compensation inductor 320. In particular, the second measurement V_{cs2} is indicative of, or associated with, a derivative of the complete frequency characteristics of the current i_{c} flowing through the compensation inductor 320, where the complete frequency characteristics of the current i, flowing through the compensation inductor 320 refers to both the low-frequency characteristics and the high-frequency characteristics of the current i_{c} flowing through the compensation inductor 320. Stated another way, the second measurement V_{cs2} is indicative of, or associated with, the slew rate of the current i_{c} flowing through the compensation inductor 320.

As described above, the first measurement V_{cs1} generated by the first current sensing circuit 325 is indicative of, or associated with, a value of the first phase current i₁ flowing through the primary winding of the first transformer 315-1 minus the high-frequency characteristics of the current i_{c} flowing through the compensation inductor 320. Therefore, if the first measurement V_{cs1} is combined with the high-frequency characteristics of the current i, flowing through the compensation inductor 320, which are the low-frequency characteristics included in the second measurement V_{cs2}, the resultant measurement would be a signal indicative of, or associated with, the value of the first phase current i₁ flowing through the primary winding of the first transformer 315-1.

The filter 510 included in the multiphase TLVR 500 is configured to filter, or modify, the second measurement V_{cs2} generated by the second current sensing circuit 505. In particular, the filter 510 is implemented as a low-pass filter that filters out the high-frequency characteristics from the second measurement V_{cs2}. The filter 510 includes a current sense resistor R_{Lc}, a current sense capacitor C_{Lc}, and an optional gain adjusting resistor R_{Lc_k}. The first terminal of the current sense resistor R_{Lc} is coupled to the output of the second current sensing circuit 505 (e.g., at the first terminal of the current sense resistor R_{cs_Lc}) and the second terminal of the current sense resistor R_{Lc} is coupled to the first terminal of the current sense capacitor C_{Lc}. The current sense capacitor C_{Lc} is coupled between the second terminal of the current sense resistor R_{Lc} and the reference voltage V_{c_ref}. The optional gain adjusting resistor R_{Lc_k} is coupled between the second terminal of the current sense resistor R_{Lc} and the reference voltage V_{c_ref}.

In operation, the filter 510 generates, based on the second measurement V_{cs2}, a modified second measurement V_{csc} at the first terminal of the current sense capacitor C_{Lc}. This modified second measurement V_{csc} generated by the filter 510 is indicative of, or associated with, the frequency characteristics of the current i, flowing through the compensation inductor 320 that are less than a cutoff frequency. Here, the value of this cutoff frequency is dependent on the resistance of the current sense resistor R_{Lc} included in the filter 510 and the capacitance of the current sense capacitor C_{Lc} included in the filter 510. The filter 335 outputs the modified second measurement V_{csc} to the voltage regulator 310 for controlling operation of the switching modules 305.

Notably, when the value of the modified second measurement V_{csc} generated by the filter 510 is expressed in the s-domain using Equation 6 below, it can be seen that Equation 6 is equal to Equation 2 described above, which is used to express the value of the modified second measurement V_{csc} generated by the filter 335 included in the multiphase TLVR 300. That is, the value of the modified second measurement V_{csc} generated by the filter 510 is equal to the value of modified second measurement V_{csc} generated by the filter 335 included in the multiphase TLVR 300.

$${V}_{c s c} ( s ) = DC {R}_{c} \times {i}_{c} ( s ) \times \frac{s {R}_{cs\_Lc} {C}_{cs\_Lc}}{1 + s {R}_{L c} {C}_{L c}} + {V}_{c\_ref} ( s ) \qquad ( 6 )$$

Where V_{csc}(S) is the modified second measurement generated by the filter 510, DCR, is the DC resistance of the compensation inductor L_{c}, i_{c}(S) is the current flowing through the compensation inductor 320, R_{cs_Lc} is the resistance of the current sense resistor included in the second current sensing circuit 505, C_{cs_Lc} is the capacitance of the current sense capacitor included in the second current sensing circuit 505, R_{Lc} is the resistance of the current sense resistor included in the filter 510, C_{Lc} is the capacitance of the current sense capacitor included in the filter 510, and V_{c_ref} is the reference voltage.

Because the modified second measurement V_{csc} generated by the filter 510 is equal to the modified second measurement V_{csc} generated by the filter 335, the modified second measurement V_{csc} generated by the filter 510 corresponds to, or is associated with, the high-frequency characteristics of the current i, flowing through the compensation inductor 320. Moreover, because the modified second measurement V_{csc} generated by the filter 510 is equal to the modified second measurement V_{csc} generated by the filter 335, the multiphase TLVR 500, which includes the second current sensing circuit 505 implemented as a high-pass filter and a filter 510 implemented as a low-pass filter, can be controlled in the same manner as described above with respect to the multiphase TLVR 300, which includes the second current sensing circuit 330 implemented as a low-pass filter and a filter 335 implemented as a high-pass filter. Accordingly, the operation of the voltage regulator 310 described above with respect to FIGS. 3 and 4 is also applicable to the operation of the voltage regulator 310 included in the multiphase TLVR 500.

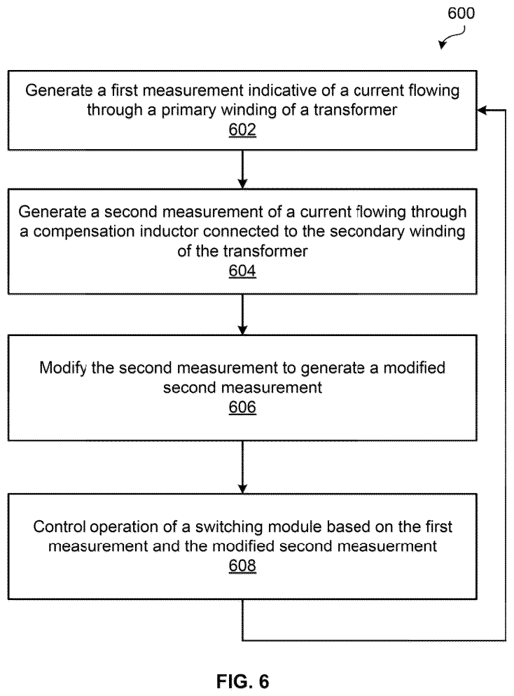

FIG. 6 sets forth a flow diagram of method steps for sensing current in a multiphase TLVR, according to various embodiments. Although the method steps are described in conjunction with the systems of FIGS. 3-5, persons skilled in the art will understand that any system configured to perform the method steps in any order falls within the scope of the present disclosure. In some examples, one or more of the processes 602-608 of method 600 are performed by the multiphase TLVR 300. In other examples, one or more of the processes 602-608 of method 600 are performed by the multiphase TLVR 500.

At a process 602, a first current sensing circuit generates a first measurement associated with a current flowing through a primary winding of a transformer. For example, the first current sensing circuit 325 included in the multiphase TLVR 300 generates a first measurement V_{cs1} that is associated with the first phase current i₁ flowing through the primary winding of the first transformer 315-1 included in the multiphase TLVR 300. As another example, the first current sensing circuit 325 included in the multiphase TLVR 500 generates a first measurement V_{cs1} that is associated with the first phase current i₁ flowing through the primary winding of the first transformer 315-1 included in the multiphase TLVR 500.

At a process 604, a second current sensing circuit generates a second measurement associated with a current flowing through a compensation inductor coupled to the secondary winding of the transformer. For example, the second current sensing circuit 330 included in the multiphase TLVR 300 generates a second measurement V_{cs2} that is associated with the current i, flowing through the compensation inductor 320 included in the multiphase TLVR 300. As another example, the second current sensing circuit 505 included in the multiphase TLVR 500 generates a second measurement V_{cs2} that is associated with the current i_{c} flowing through the compensation inductor 320 included in the multiphase TLVR 500.

At a process 606, a filter modifies the second measurement associated with the current flowing through the compensation inductor to generate a modified version of the second measurement. For example, the filter 335 included in the multiphase TLVR 300 generates a modified second measurement V_{csc} that is associated with the current i_{c} flowing through the compensation inductor 320 included in the multiphase TLVR 300. As another example, the filter 510 included in the multiphase TLVR 500 generates a modified second measurement V_{csc} that is associated with the current i_{c} flowing through the compensation inductor 320 included in the multiphase TLVR 500.

At a process 608, operation of a switching module is controlled based on the first measurement and the modified second measurement. In one example, the voltage regulator 310 included the multiphase TLVR 300 and/or the multiphase TLVR 500 controls operation of one or more switching modules 305 based on the first measurement V_{cs1} and the modified second measurement V_{csc}. In some examples, the voltage regulator 310 included in the multiphase TLVR 300 and/or the multiphase TLVR 500 additionally controls operation of one or more switching modules 305 based on an output voltage Vₒᵤₜ and/or a reference voltage V_{c_ref}

In some examples, the voltage regulator 310 combines the first measurement V_{cs1} and the modified second measurement V_{csc} into a combined measurement, such as combined measurement V_{cs_final}, that is associated with the total phase current flowing through the multiphase TLVR 300 and/or the multiphase TLVR 500. In such examples, the voltage regulator 310 included the multiphase TLVR 300 and/or the multiphase TLVR 500 controls operation of one or more switching modules 305 based on the combined measurement V_{cs_final}. In some examples, controlling operation of the switch module includes generating one or more controls signals based on one or more of the output voltage Vₒᵤₜ, the reference voltage V_{c_ref}, the first measurement V_{cs1}, the modified second measurement V_{csc}, and/or the combined measurement V_{cs_final}. In such examples, operation of the switch module is controlled in accordance with the one or more control signals.

After the process 608, the method 600 returns to process 602 where the first current sensing circuit generates another first measurement associated with the current flowing through the primary winding of the transformer. When the first current sensing circuit generates another first measurement associated with the current flowing through the primary winding of the transformer, the method 600 repeats.

When compared to the DCR sensing circuit 120 included in the multiphase TLVR 100 of the prior art, which only senses the current flowing through the primary winding of the transformer 110-1, the first current sensing circuit 325, the second current sensing circuit 330, and the filter 335 included in the multiphase TLVR 300 combine to generate a phase current measurement, such as the combined measurement V_{cs_final}, that more accurately reflects that actual phase current that is flowing through the multiphase TLVR 300. In a similar manner, the first current sensing circuit 325, the second current sensing circuit 505, and the filter 510 included in the multiphase TLVR 500 combine to generate a phase current measurement, such as the combined measurement V_{cs_final}, that more accurately reflects that actual phase current that is flowing through the multiphase TLVR 500.

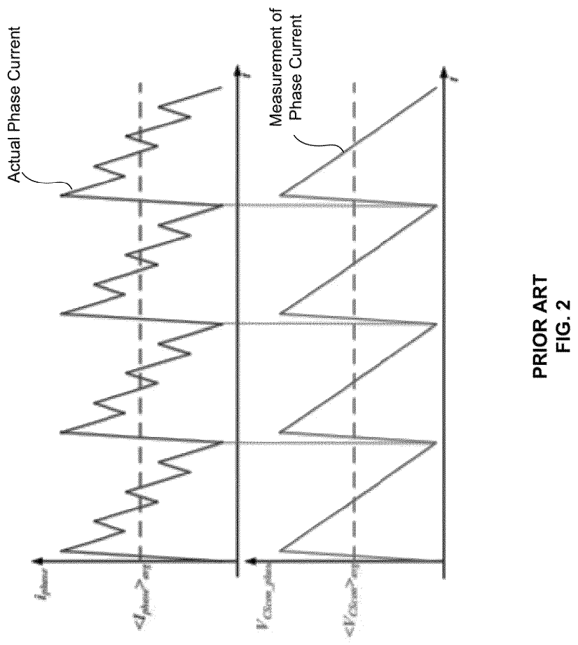

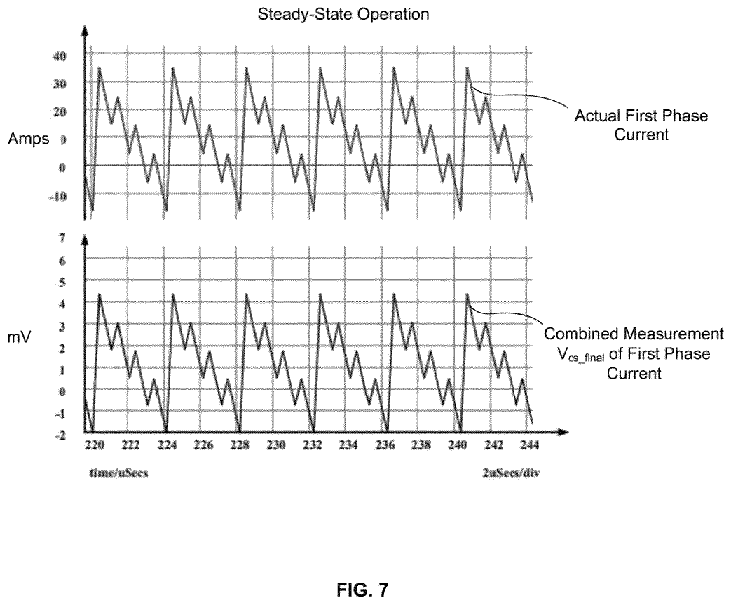

FIG. 7 illustrates an actual phase current and a measurement of that phase current when a multiphase TLVR is operating in a steady state, according to various embodiments. For example, FIG. 7 illustrates the actual first phase current flowing through the multiphase TLVR 300 during steady-state operation of the multiphase TLVR 300 and the combined measurement V_{cs_final} that is generated during steady-state operation of the multiphase TLVR 300. Steady-state operation of the multiphase TLVR 300 refers to operation of the multiphase TLVR 300 during times in which little to no load transients are present. As shown in FIG. 7, the combined measurement V_{cs_final} accurately reflects the actual first phase current flowing through the multiphase TLVR 300 during steady-state operation of the multiphase TLVR 300. By comparison, as shown in FIG. 2, the phase current measurement that is generated by the DCR sensing circuit 120 included in the multiphase TLVR 100 of the prior art is distorted relative to the actual phase current flowing through the multiphase TLVR 100 of the prior art.

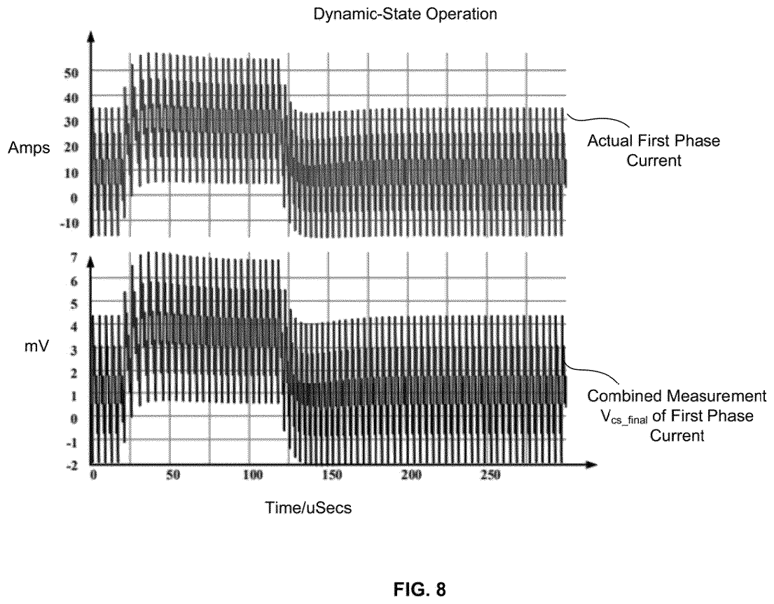

FIG. 8 illustrates an actual phase current and a measurement of that phase current when a multiphase TLVR is operating in a dynamic state, according to various embodiments. For example, FIG. 8 illustrates the actual first phase current flowing through the multiphase TLVR 300 during dynamic-state operation of the multiphase TLVR 300 and the combined measurement V_{cs_final} that is generated during dynamic-state operation of the multiphase TLVR 300. Dynamic-state operation of the multiphase TLVR 300 refers to operation of the multiphase TLVR 300 at times in which load transients are present. As shown in FIG. 8, the combined measurement V_{cs_final} also accurately reflects the actual first phase current flowing through the multiphase TLVR 300 during dynamic-state operation of the multiphase TLVR 300.

As described above with respect to FIGS. 3-8, the actual first phase current flowing through a multiphase TLVR, such as the multiphase TLVR 300 and/or the multiphase TLVR 500, can be accurately measured by generating a first measurement associated with the first phase current i₁ flowing through a primary winding of the first transformer 315-1 and by generating a second measurement associated with the current i_{c} flowing through the compensation inductor 320. With minor modifications to the multiphase TLVR 300 and/or the multiphase TLVR 500, it is further possible to accurately measure the multiphase, or total, current flowing through the multiphase TLVR 300 and/or the multiphase TLVR 500.

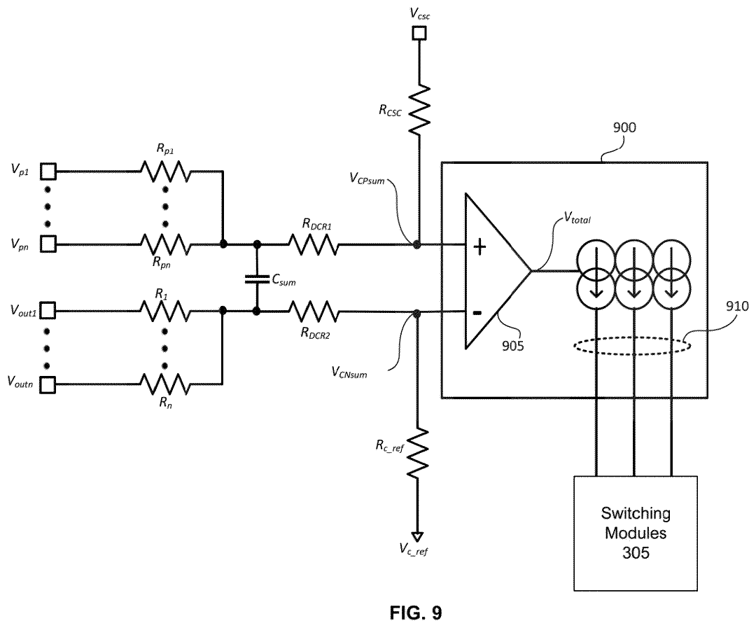

FIG. 9 illustrates a circuit diagram of a voltage regulator that may be incorporated into a multiphase TLVR, according to various other embodiments. For example, FIG. 9 illustrates a voltage regulator 900, which is a modified version of the voltage regulator 310 included in the multiphase TLVRs 300 and 500. The voltage regulator 900 can be implemented in a multiphase TLVR, such as the multiphase TLVR 300, the multiphase TLVR 500, and/or some other multiphase TLVR. For explanatory purposes, the voltage regulator 900 will be described with respect to the multiphase TLVR 300. However, persons skilled in the art will understand that description of the voltage regulator 900 with respect to the multiphase TLVR 300 is also applicable to scenarios in which the voltage regulator 900 is implemented in a different multiphase TLVR, such as the multiphase TLVR 500. Furthermore, although many of the components illustrated in FIG. 9 are shown to be included in the voltage regulator 900, it should be understood that in some examples, one or more of these components can be located externally and coupled to the voltage regulator 900. The voltage regulator 900 can be implemented as any suitable control device and/or circuit for controlling operation of switching modules 305. For example, voltage regulator 900 can be implemented as one or more of an analog control circuit, a digital control circuit, a microprocessor, an integrated circuit, and/or any other suitable control device for controlling operation of switching modules 305.

As shown in FIG. 9, the respective phase voltages Vₚ generated by the switching modules 305 are provided as inputs to the modified voltage regulator 900. For example, the first phase voltage Vₚ₁ generated by the first switching module 305-1 through the Nth phase voltage Vₚₙ generated by the Nth switching module 305-N are provided as inputs to the voltage regulator 900. Each of the phase voltages Vₚ input to the voltage regulator 900 is coupled in series with a respective phase resistance Rₚ included in a resistor network that is coupled to the voltage regulator 900. For example, the first phase voltage Vₚ₁ is coupled in series with the first phase resistance Rₚ₁ and the Nth phase voltage Vₚₙ is coupled in series with the Nth phase resistance Rₚₙ. As further shown in FIG. 9, the output nodes of phase resistors Rₚ are coupled to a first node of a summing capacitor Cₛᵤₘ that is coupled to the voltage regulator 900.

As further shown in FIG. 9, for each phase voltage Vₚ that is input to the voltage regulator 900, a corresponding copy of the output voltage Vₒᵤₜ is input to the voltage regulator 900. For example, since the first through Nth phase voltages Vₚ₁-Vₚₙ are input to the voltage regulator 900, N corresponding copies of the output voltage Vₒᵤₜ₁-Vₒᵤₜₙ are input to the voltage regulator 900. Each of the copies of the output voltages Vₒᵤₜ input to the voltage regulator 900 is coupled in series with a respective input resistor R included in a resistor network that is coupled to the voltage regulator 900. For example, the first copy of the output voltage Vₒᵤₜ₁ is coupled in series with the first input resistance R₁ and the Nth copy of the output voltage Vₒᵤₜₙ is coupled in series with the Nth input resistance Rn. As further shown in FIG. 9, the output nodes of input resistors Rn are coupled to the second node of the summing capacitor Cₛᵤₘ that is coupled to the voltage regulator 900. The summing capacitor Cₛᵤₘ is coupled to the voltage regulator 900 by a first sense resistor R_{DCR1} and a second sense resistor R_{DCR2}. For example, the first node of the summing capacitor Cₛᵤₘ is coupled to the first node of the first sense resistor R_{DCR1} and the second node of the summing capacitor Cₛᵤₘ is coupled to the first node of the second sense resistor R_{DCR2}.

In the illustrated example of FIG. 9, each of the phase resistors Rₚ has the same resistance value. In addition, each of the input resistors R has the same resistance value. Furthermore, the resistance value of each of the phase resistors Rₚ is equal to the resistance value of each of the input resistors R. In some examples, the phase resistors Rₚ and/or the input resistors R have different resistance values.

As further shown in FIG. 9, the summing capacitor Cₛᵤₘ is coupled to the voltage regulator 900 by a first sense resistor R_{DCR1} and a second sense resistor R_{DCR2}. For example, the first node of the summing capacitor Cₛᵤₘ is coupled to the first node of the first sense resistor R_{DCR1} and the second node of the summing capacitor Cₛᵤₘ is coupled to the first node of the second sense resistor R_{DCR2} having a first node that is coupled to the second node of the summing capacitor Cₛᵤₘ.

As further shown in FIG. 9, the modified second measurement V_{csc} is provided as an input to the voltage regulator 900. As described above, the modified second measurement V_{csc} is output by the filter 335 included in the multiphase TLVR 300 and is a modified version of the second measurement V_{cs2} generated by the second current sensing circuit 330. Moreover, the modified second measurement V_{csc} is associated with the current i_{c}, and more particularly the high-frequency characteristics of the current i_{c}, flowing through the compensation inductor 320. The modified second measurement V_{csc} is coupled in series with a sense resistor R_{csc} that is coupled to the voltage regulator 900. As shown in FIG. 9, the second node of the first sense resistor R_{DCR1} is coupled to the second node of the sense resistor R_{csc} at positive input node of the voltage regulator 900. Based on the properties of a resistor divider network, the voltage of the second node of the first sense resistor R_{DCR1} and the voltage of the second node of the sense resistor R_{csc} is combined into a positive combined measurement V_{CPsum} at the positive input node of the voltage regulator 900. This positive combined measurement V_{CPsum} is provided as an input to the positive terminal of the comparator 905 included in the voltage regulator 900.

As further shown in FIG. 9, the reference voltage V_{c_ref} is provided as an input to the voltage regulator 900. As described above, the reference voltage V_{c_ref} can be a non-zero reference voltage that is coupled, or applied to, a node of the compensation inductor 320. The reference voltage V_{c_ref} is coupled in series with a sense resistor R_{c_ref} that is coupled to the voltage regulator 900. As shown in FIG. 9, the second node of the second sense resistor R_{DCR2} is coupled to the second node of the sense resistor R_{c_ref} at a negative input node of the voltage regulator 900. Based on the properties of a resistor divider network, the voltage of the second node of the second sense resistor R_{DCR2} and the voltage of the second node of the sense resistor R_{c_ref} is combined into a negative combined measurement V_{CNsum} at the negative input node of the voltage regulator 900. This negative combined measurement V_{CNsum} is provided as an input to the negative terminal of the comparator 905 included in the voltage regulator 900.

Based on the positive combined measurement V_{Cpsum} input to the positive terminal and the negative combined measurement V_{CNsum} input to the negative terminal, the comparator 905 generates a total measurement Vₜₒₜₐₗ that is associated with the total current flowing through the multiphase TLVR 300. As shown in FIG. 9, the total measurement Vₜₒₜₐₗ is determined based in part on each of the phase voltages Vₚ generated by the switching modules 305 as well as the modified second measurement V_{csc} that is associated with the high-frequency characteristics of the current i_{c} flowing through the compensation inductor 320. The voltage regulator 900 can then optionally generate, based on the total measurement Vₜₒₜₐₗ, one or more control signals 910 for controlling operation of the switching modules 305. In some instances, it desirable to control operation of the switching modules 305 based on the total current flowing through the multiphase TLVR 300 when implanting total current protection functions or droop control of the multiphase TLVR 300. In some examples, the one or more control signals are PWM signals 910.

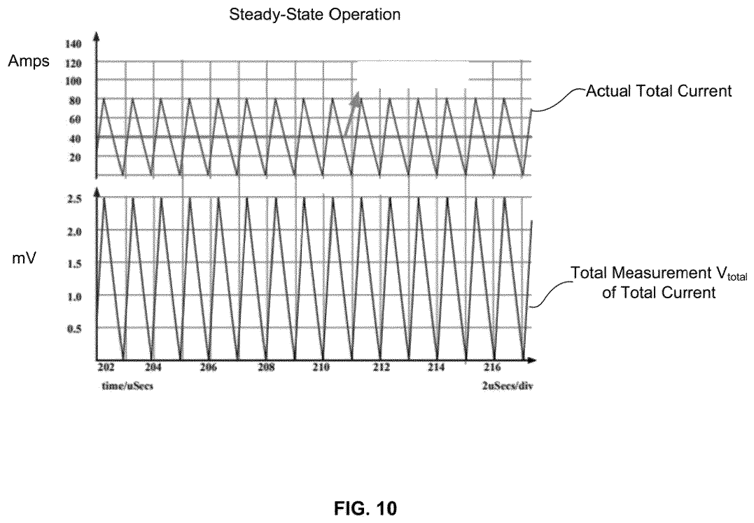

FIG. 10 illustrates an actual total current and a measurement of that total current when a multiphase TLVR implementing the voltage regulator of FIG. 9 is operating in a steady state, according to various embodiments. For example, FIG. 10 illustrates the actual total current flowing through the multiphase TLVR 300 during steady-state operation of the multiphase TLVR 300 implementing the voltage regulator 900 and the total measurement Vₜₒₜₐₗ that is generated during steady-state operation of the multiphase TLVR 300 implementing the voltage regulator 900. As shown in FIG. 10, the total measurement Vₜₒₜₐₗ accurately reflects the actual total current flowing through the multiphase TLVR 300 during steady-state operation of the multiphase TLVR 300 implementing the voltage regulator 900.

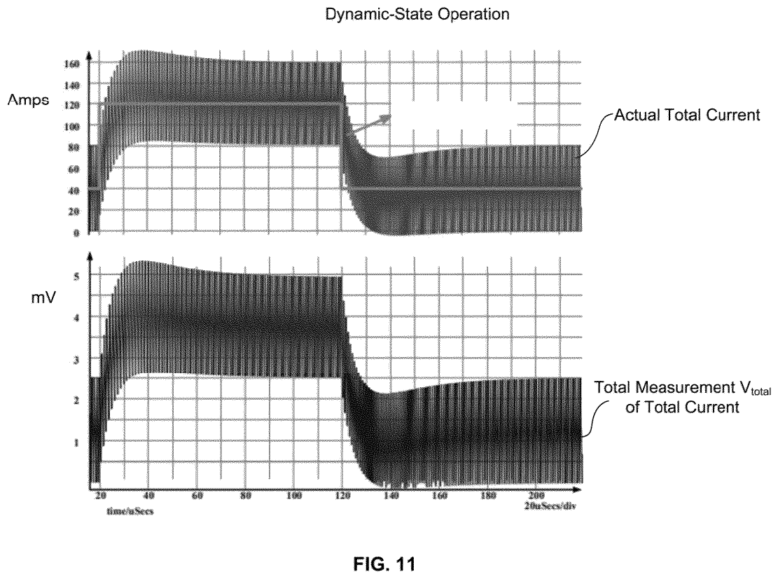

FIG. 11 illustrates an actual total current and a measurement of that total current when a multiphase TLVR implementing the voltage regulator of FIG. 9 is operating in a dynamic state, according to various other embodiments. For example, FIG. 11 illustrates the actual total current flowing through the multiphase TLVR 300 during dynamic-state operation of the multiphase TLVR 300 implementing the voltage regulator 900 and the total measurement Vₜₒₜₐₗ that is generated during dynamic-state operation of the multiphase TLVR 300 implementing the voltage regulator 900. As shown in FIG. 11, the total measurement Vₜₒₜₐₗ also accurately reflects the actual total current flowing through the multiphase TLVR 300 during dynamic-state operation of the multiphase TLVR 300 implementing the voltage regulator 900.

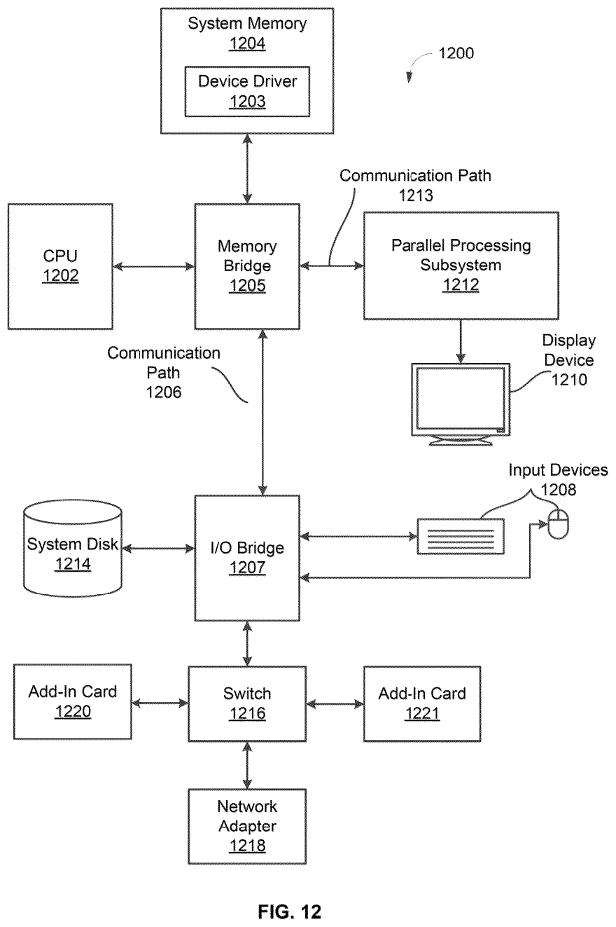

FIG. 12 is a block diagram illustrating a computer system 1200 configured to implement one or more aspects of various embodiments. In some embodiments, computer system 1200 is a machine or processing node operating in a data center, cluster, or cloud computing environment that provides scalable computing resources (optionally as a service) over a network. In some embodiments, the computer system 1200 is a high-performance computing system or device such as, without limitation, a server machine, a server platform, a desktop machine, a laptop machine, a hand-held/mobile device, or a wearable device.

As will be described in more detail below, the computer system 1200 includes one or more electronic components that can be powered by a multiphase TLVR, such as the multiphase TLVR 300 or the multiphase TLVR 500 described herein. Stated another way, the computer system 1200 includes and/or is coupled to one or more multiphase TLVRs, such as the multiphase TLVR 300 or the multiphase TLVR 500, that provide power to one or more of the electronic components of the computer system 1200. For example, one or more electronic components included in the computer system 1200 can be implemented as the load R_{Load} included in the multiphase TLVR 300 or the multiphase TLVR 500.

In various embodiments, computer system 1200 includes, without limitation, a central processing unit (CPU) 1202 and a system memory 1204 coupled to a parallel processing subsystem 1212 via a memory bridge 1205 and a communication path 1213. Memory bridge 1205 is further coupled to an I/O (input/output) bridge 1207 via a communication path 1206, and I/O bridge 1207 is, in turn, coupled to a switch 1216. In operation of the computer system 1200, one or more of the CPU 1202, the system memory 1204, and/or the parallel processing subsystem 1212 can be coupled to and powered by a multiphase TLVR, such as the multiphase TLVR 300 or the multiphase TLVR 500 described herein.

In one embodiment, I/O bridge 1207 is configured to receive user input information from optional input devices 1208, such as a keyboard or a mouse, and forward the input information to CPU 1202 for processing via communication path 1206 and memory bridge 1205. In some embodiments, computer system 1200 may be a server machine in a cloud computing environment. In such embodiments, computer system 1200 may not have input devices 1208. Instead, computer system 1200 may receive equivalent input information by receiving commands in the form of messages transmitted over a network and received via the network adapter 1218. In one embodiment, switch 1216 is configured to provide connections between I/O bridge 107 and other components of the computer system 1200, such as a network adapter 1218 and various add-in cards 1220 and 1221.

In one embodiment, I/O bridge 1207 is coupled to a system disk 1214 that may be configured to store content and applications and data for use by CPU 1202 and parallel processing subsystem 1212. In one embodiment, system disk 1214 provides non-volatile storage for applications and data and may include fixed or removable hard disk drives, flash memory devices, and CD-ROM (compact disc read-only-memory), DVD-ROM (digital versatile disc-ROM), Blu-ray, HD-DVD (high definition DVD), or other magnetic, optical, or solid state storage devices. In various embodiments, other components, such as universal serial bus or other port connections, compact disc drives, digital versatile disc drives, film recording devices, and the like, may be coupled to I/O bridge 1207 as well.

In various embodiments, memory bridge 1205 may be a Northbridge chip, and I/O bridge 1207 may be a Southbridge chip. In addition, communication paths 1206 and 1213, as well as other communication paths within computer system 1200, may be implemented using any technically suitable protocols, including, without limitation, AGP (Accelerated Graphics Port), HyperTransport, or any other bus or point-to-point communication protocol known in the art.

In some embodiments, parallel processing subsystem 1212 includes a graphics subsystem that delivers pixels to an optional display device 1210 that may be any conventional cathode ray tube, liquid crystal display, light-emitting diode display, or the like. In such embodiments, the parallel processing subsystem 1212 incorporates circuitry optimized for graphics and video processing, including, for example, video output circuitry. Such circuitry may be incorporated across one or more parallel processing units (PPUs), also referred to herein as parallel processors, included within parallel processing subsystem 1212. In other embodiments, the parallel processing subsystem 1212 incorporates circuitry optimized for general purpose and/or compute processing. Again, such circuitry may be incorporated across one or more PPUs included within parallel processing subsystem 1212 that are configured to perform such general purpose and/or compute operations. In yet other embodiments, the one or more PPUs included within parallel processing subsystem 1212 may be configured to perform graphics processing, general purpose processing, and compute processing operations. System memory 1204 includes at least one device driver 1203 configured to manage the processing operations of the one or more PPUs within parallel processing subsystem 1212. In some embodiments, the one or more PPUs can be powered by one or more multiphase TLVRs, such as the multiphase TLVR 300 or the multiphase TLVR 500 described herein.

In various embodiments, parallel processing subsystem 1212 may be integrated with one or more of the other elements of FIG. 12 to form a single system. For example, parallel processing subsystem 1212 may be integrated with CPU 1202 and other connection circuitry on a single chip to form a system on chip (SoC).

In one embodiment, CPU 1202 is the master processor of computer system 1200, controlling and coordinating operations of other system components. In one embodiment, CPU 1202 issues commands that control the operation of PPUs. In some embodiments, communication path 1213 is a PCI Express link, in which dedicated lanes are allocated to each PPU, as is known in the art. Other communication paths may also be used. PPU advantageously implements a highly parallel processing architecture. A PPU may be provided with any amount of local parallel processing memory (PP memory).

It will be appreciated that the system shown herein is illustrative and that variations and modifications are possible. The connection topology, including the number and arrangement of bridges, the number of CPUs 1202, and the number of parallel processing subsystems 1212, may be modified as desired. For example, in some embodiments, system memory 1204 could be coupled to CPU 1202 directly rather than through memory bridge 1205, and other devices would communicate with system memory 1204 via memory bridge 1205 and CPU 1202. In other embodiments, parallel processing subsystem 1212 may be coupled to I/O bridge 1207 or directly to CPU 102, rather than to memory bridge 1205. In still other embodiments, I/O bridge 1207 and memory bridge 1205 may be integrated into a single chip instead of existing as one or more discrete devices. Lastly, in certain embodiments, one or more components shown in FIG. 12 may not be present. For example, switch 1216 could be eliminated, and network adapter 1218 and add-in cards 1220, 1221 would connect directly to I/O bridge 1207.

In sum, a multiphase trans-inductor voltage regulator (TLVR) provides an output voltage to a load, such as an electronic component included in a high-performance computing system or device. The multiphase TLVR includes a plurality of switching modules that generate respective phases of the output voltage and a plurality of transformers, where each transformer includes a primary winding that is coupled to a respective switching module and a secondary winding that is coupled in series with the secondary windings of the other transformers. The multiphase TLVR further includes a first current sensing circuit that generates a first measurement indicative of a phase current flowing through a primary winding of a first transformer included in the plurality of transformers. The multiphase TLVR further includes a second current sensing circuit that generates a second measurement indicative of a current flowing through a compensation inductor that is coupled in series with the secondary windings of the plurality of transformers. A filter connected to the second current sensing circuit included in the multiphase TLVR modifies the second measurement to generate a modified second measurement that is associated with high-frequency characteristics of the current flowing through the compensation inductor. In operation, a voltage regulator included in the multiphase TLVR controls the switching modules based on the first measurement and the modified second measurement.

At least one technical advantage of the disclosed techniques relative to the prior art is that, with the disclosed techniques, phase current flowing through a multiphase TLVR can be accurately sensed. More specifically, with the disclosed techniques, an accurate phase current measurement and an accurate total current measurement can be generated by sensing the current flowing through a primary winding of a transformer included in a multiphase TLVR and by sensing current flowing through a compensation inductor coupled in series with the secondary windings of the transformers included in the multiphase TLVR. Accordingly, with the disclosed techniques, accurate phase current and total current measurements can be generated, thereby improving the overall performance of the multiphase TLVR relative to what can be achieved using prior art designs. Consequently, with the disclosed techniques, a multiphase TLVR can provide electronic components more accurate current and voltage regulation as well as enhanced phase over-current-protection. These technical advantages represent one or more technological improvements over prior art approaches.

1. According to some embodiments, a trans-inductor voltage regulator comprises a first current sensing circuit that generates a first measurement associated with a current flowing through a primary winding of a transformer; a second current sensing circuit that generates a second measurement associated with a current flowing through a compensation inductor coupled to a secondary winding of the transformer; a filter coupled to the second current sensing circuit that modifies the second measurement to generate a modified second measurement; and a voltage regulator that, in operation, controls a switching module based on the first measurement and the modified second measurement.

2. The trans-inductor voltage regulator according to clause 1, wherein the second current sensing circuit comprises a high-pass filter.

3. The trans-inductor voltage regulator according to clause 1 or clause 2, wherein the second current sensing circuit comprises a low-pass filter.

4. The trans-inductor voltage regulator according to any of clauses 1-3, wherein a first node of the compensation inductor is coupled to the secondary winding of the transformer and a second node of the compensation inductor is coupled to a non-zero reference voltage.

5. The trans-inductor voltage regulator according to any of clauses 1-4, wherein the voltage regulator controls the switching module based on the first measurement, the modified second measurement, and the non-zero reference voltage.

6. The trans-inductor voltage regulator according to any of clauses 1-5, wherein the modified second measurement is associated with one or more high-frequency characteristics of the current flowing through the compensation inductor.

7. The trans-inductor voltage regulator according to any of clauses 1-6, wherein the second current sensing circuit comprises a high-pass filter, and the filter comprises a low-pass filter.

8. The trans-inductor voltage regulator according to any of clauses 1-7, wherein the second current sensing circuit comprises a low-pass filter, and the filter comprises a high-pass filter.

9. The trans-inductor voltage regulator according to any of clauses 1-8, further comprising a second transformer that includes a second secondary winding that is coupled in series with the secondary winding of the transformer and the compensation inductor.

10. The trans-inductor voltage regulator according to any of clauses 1-9, wherein a first node of the compensation inductor is coupled to the secondary winding of the transformer, and a second node of the compensation inductor is coupled to a reference voltage.

11. The trans-inductor voltage regulator according to any of clauses 1-10, further comprising a second switching module, and wherein the voltage regulator, in operation, controls the second switching module based on the first measurement and the second measurement.

12. The trans-inductor voltage regulator according to any of clauses 1-11, wherein the second sensing circuit comprises a sense resistor that is coupled to an input of the compensation inductor and a sense capacitor that is coupled between the sense resistor and an output of the compensation inductor.

13. The trans-inductor voltage regulator according to any of clauses 1-12, wherein the second sensing circuit comprises a sense capacitor that is coupled to an input of the compensation inductor and a sense resistor that is coupled between the sense capacitor and an output of the compensation inductor.

14. A method for sensing current in a trans-inductor voltage regulator, the method comprising generating a first measurement associated with a current flowing through a primary winding of a transformer; generating a second measurement associated with a current flowing through a compensation inductor that is coupled to a secondary winding of the transformer; modifying the second measurement to generate a modified second measurement; and controlling a switching module based on the first measurement and the modified second measurement.

15. The method according to clause 14, further comprising generating a control signal based on the first measurement and the modified second measurement; and controlling the switching module based on the control signal.

16. The method according to clause 14 or clause 15, further comprising combining the first measurement and the modified second measurement into a combined measurement associated with a total phase current flowing through the voltage regulator; and controlling the switching module based on the combined measurement.

17. The method according to any of clauses 14-16, wherein modifying the second measurement includes removing low-frequency characteristics from the second measurement.

18. The method according to any of clauses 14-17, wherein generating the first measurement includes sensing a voltage across the primary winding of the transformer.

19. The method according to any of clauses 14-18, wherein generating the second measurement includes sensing a voltage across the compensation inductor.

20. A system comprising an electronic component and a trans-inductor voltage regulator that, in operation, provides a voltage to the electronic component. The voltage regulator comprises a first current sensing circuit that generates a first measurement associated with a current flowing through a primary winding of a transformer; a second current sensing circuit that generates a second measurement associated with a current flowing through a compensation inductor coupled to a secondary winding of the transformer; a filter coupled to the second current sensing circuit that modifies the second measurement to generate a modified second measurement; and a voltage regulator that, in operation, controls a switching module based on the first measurement and the modified second measurement.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

The flowchart and block diagrams in the figures illustrate the architecture, functionality, and operation of possible implementations of systems and methods according to various embodiments of the present disclosure. It should also be noted that, in some implementations, the processes noted in the blocks may occur out of the order noted in the figures. For example, two blocks shown in succession may, in fact, be executed substantially concurrently, or the blocks may sometimes be executed in the reverse order, depending upon the functionality involved.

While the preceding is directed to embodiments of the present disclosure, other and further embodiments of the disclosure may be devised without departing from the basic scope thereof, and the scope thereof is determined by the claims that follow.

What is claimed is:

1. A trans-inductor voltage regulator comprising:
a first current sensing circuit that generates a first measurement associated with a current flowing through a primary winding of a transformer;
a second current sensing circuit that generates a second measurement associated with a current flowing through a compensation inductor coupled to a secondary winding of the transformer;
a filter coupled to the second current sensing circuit that modifies the second measurement to generate a modified second measurement; and
a voltage regulator that, in operation, controls a switching module based on the first measurement and the modified second measurement.

2. The trans-inductor voltage regulator of claim 1, wherein the second current sensing circuit comprises a high-pass filter.

3. The trans-inductor voltage regulator of claim 1, wherein the second current sensing circuit comprises a low-pass filter.

4. The trans-inductor voltage regulator of claim 1, wherein a first node of the compensation inductor is coupled to the secondary winding of the transformer and a second node of the compensation inductor is coupled to a non-zero reference voltage.

5. The trans-inductor voltage regulator of claim 4, wherein the voltage regulator controls the switching module based on the first measurement, the modified second measurement, and the non-zero reference voltage.

6. The trans-inductor voltage regulator of claim 1, wherein the modified second measurement is associated with one or more high-frequency characteristics of the current flowing through the compensation inductor.

7. The trans-inductor voltage regulator of claim 1, wherein the second current sensing circuit comprises a high-pass filter, and the filter comprises a low-pass filter.

8. The trans-inductor voltage regulator of claim 1, wherein the second current sensing circuit comprises a low-pass filter, and the filter comprises a high-pass filter.

9. The trans-inductor voltage regulator of claim 1, further comprising a second transformer that includes a second secondary winding that is coupled in series with the secondary winding of the transformer and the compensation inductor.

10. The trans-inductor voltage regulator of claim 1, wherein a first node of the compensation inductor is coupled to the secondary winding of the transformer, and a second node of the compensation inductor is coupled to a reference voltage.

11. The trans-inductor voltage regulator of claim 1, further comprising a second switching module, and wherein the voltage regulator, in operation, controls the second switching module based on the first measurement and the second measurement.

12. The trans-inductor voltage regulator of claim 1, wherein the second sensing circuit comprises a sense resistor that is coupled to an input of the compensation inductor and a sense capacitor that is coupled between the sense resistor and an output of the compensation inductor.

13. The trans-inductor voltage regulator of claim 1, wherein the second sensing circuit comprises a sense capacitor that is coupled to an input of the compensation inductor and a sense resistor that is coupled between the sense capacitor and an output of the compensation inductor.

14. A method for sensing current in a trans-inductor voltage regulator, the method comprising:
generating a first measurement associated with a current flowing through a primary winding of a transformer;
generating a second measurement associated with a current flowing through a compensation inductor that is coupled to a secondary winding of the transformer;
modifying the second measurement to generate a modified second measurement; and
controlling a switching module based on the first measurement and the modified second measurement.

15. The method of claim 14, further comprising:
generating a control signal based on the first measurement and the modified second measurement; and
controlling the switching module based on the control signal.

16. The method of claim 14, further comprising:
combining the first measurement and the modified second measurement into a combined measurement associated with a total phase current flowing through the voltage regulator; and
controlling the switching module based on the combined measurement.

17. The method of claim 14, wherein modifying the second measurement includes removing low-frequency characteristics from the second measurement.

18. The method of claim 14, wherein generating the first measurement includes sensing a voltage across the primary winding of the transformer.

19. The method of claim 14, wherein generating the second measurement includes sensing a voltage across the compensation inductor.

20. A system, comprising:
an electronic component; and
a trans-inductor voltage regulator that, in operation, provides a voltage to the electronic component, the voltage regulator comprising:
a first current sensing circuit that generates a first measurement associated with a current flowing through a primary winding of a transformer;
a second current sensing circuit that generates a second measurement associated with a current flowing through a compensation inductor coupled to a secondary winding of the transformer;
a filter coupled to the second current sensing circuit that modifies the second measurement to generate a modified second measurement; and
a voltage regulator that, in operation, controls a switching module based on the first measurement and the modified second measurement.
